(19) United States
(12) Patent Application Publication
(10) Pub. No.: US 2005/0094435 A1
(43) Pub. Date: May 5, 2005

(54) Increased magnetic stability devices suitable for use as sub-micron memories

(75) Inventors: Murray Fulton Gillies, Eindhoven (NL); Kars-Michiel Hubert Lenssen, Eindhoven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V., (NL)

(21) Appl. No.: 10/499,256

(22) PCT Filed: Dec. 16, 2002
(86) PCT No.: PCT/IB02/05475

(30) Foreign Application Priority Data
Dec. 20, 2001 (EP) 01205050.6

(51) Int. Cl. G11C 11/00

(52) U.S. Cl. 365/158

(57) ABSTRACT

Magnetic device cells such as MRAM cells are described which can be used in sub-micron cell sizes. The present invention describes a method of stabilising magnetic device cells by creating a storage state where the two magnetisation directions of the spin valve are anti-parallel when no readout is performed. This avoids the problem at such small dimensions, that the parallel state of magnetisation directions in a spin valve or a spin tunnel junction become unstable. A high coercivity memory layer is combined with a low coercivity keeper layer. The read out process has also been simplified: only one pulse over the bit line and measurement of the resistance in the word line is sufficient to determine the data stored in a magnetic device cell according to the present invention.

The present invention relates to magnetic devices with anti-parallel coupling between different layers, more particularly to non-volatile magnetic memories, but also to readout heads for magnetic recording and magnetic sensors and methods of use of such devices.

Magnetic or Magnetoresistive Random Access Memory (MRAM) is currently being considered by many companies as a successor to flash memory. It is a non-volatile memory device, which means that no power is required to sustain the stored information. This is seen as an advantage over most other types of memory.

The MRAM concept was originally developed at Honeywell Corp. USA, and uses magnetisation direction in a magnetic multilayer device as information storage and the resultant resistance difference for information readout. As with all memory devices, each cell in an MRAM array must be able to store at least two states which represent either a “1” or a “0”.

Different kinds of magnetoresistive (MR) effects exist, of which the Giant Magneto-Resistance (GMR) and Tunnel Magneto-Resistance (TMR) are currently the most important ones. The GMR effect and the TMR or Magnetic Tunnel Junction (MTJ) or Spin Dependent Tunnelling (SDT) effect provide possibilities to realise a.o. non-volatile magnetic memories. These devices comprise a stack of thin films of which at least two are ferromagnetic or ferrimagnetic, and which are separated by a non-magnetic interlayer. GMR is the magneto-resistance for structures with conductor interlayers and TMR is the magneto-resistance for structures with dielectric interlayers. If a very thin conductor is placed between two ferromagnetic or ferrimagnetic films, then the effective in-plane resistance of the composite multilayer structure is smallest when the magnetisation directions of the films are parallel and largest when the magnetisation directions of the films are anti-parallel. If a thin dielectric interlayer is placed between two ferromagnetic or ferrimagnetic films, tunnelling current between the films is observed to be the largest (or thus resistance to be the smallest) when the magnetisation directions of the films are parallel and tunnelling current between the films is the smallest (or thus resistance the largest) when the magnetisation directions of the films are anti-parallel.

Magneto-resistance is usually measured as the percentage increase in resistance of the above structures going from parallel to anti-parallel magnetisation states. TMR devices provide higher percentage magneto-resistance than GMR structures, and thus have the potential for higher signals and higher speed. Recent results indicate tunnelling giving over 40% magneto-resistance, compared to 6-9% magneto-resistance in good GMR cells.

An interesting type of GMR device is popularly known as a spin valve, as described in J. M. Daughton et al., “Applications of spin dependent transport materials”, J. Phys. D: Appl. Phys. 32 (1999) R169-177. In this structure, the magnetisation of one ferromagnetic layer is pinned in one direction with a layer of anti-ferromagnetic material (such as MnO or MnFe). The magnetisation of the other layer is free to rotate but as the bits become very narrow, it tends towards either a parallel or anti-parallel alignment relative to the pinned layer in reproducible and stable states. These orientations correspond to the “0” or “1” states of the magnetic memory bit. A change in resistance is observed when the magnetisation in the two ferromagnetic layers is switched from a parallel (low resistance) state to an anti-parallel (high resistance) state or vice versa. The state of the cell can be measured by measuring the resistance.

U.S. Pat. No. 6,252,796 also describes such a spin valve cell, in which current is used in a layer to switch or reset the magnetisation direction of strongly anti-parallel coupled layers as a whole, i.e. the anti-parallel coupling is always there.

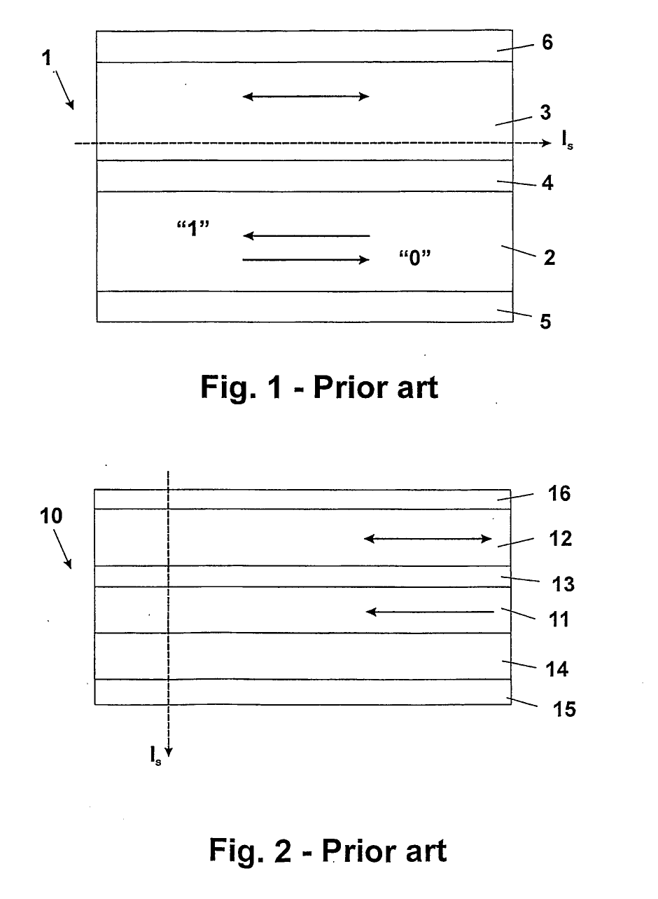

Pseudo-spin valve (PSV) cells are also known, as described in J. M. Daughton et al., “Applications of spin dependent transport materials”, J. Phys. D: Appl. Phys. 32 (1999) R169-177. A typical pseudo spin valve stack 1 is schematically shown in FIG. 1. In these devices there are two magnetic layers 2, 3 that have mismatched properties, i.e. two ferromagnetic or ferrimagnetic layers 2, 3 with different coercivities, so that one tends to switch at lower fields than the other does. The coercivity of a ferromagnetic layer can be seen as the magnetic field required for making the magnetisation change direction. Both magnetic layers 2, 3 are separated by an interlayer 4 e.g. by a Cu-spacer. A seed layer 5 is provided under the bottom magnetic layer 2 to have a good structure underneath it, and a capping layer 6, e.g. a Ta capping layer, is provided on top of the top magnetic layer 3 as an anti-oxidation layer.

Providing magnetic layers 2, 3 with different coercivities can e.g. be done by using two magnetic films of the same material, but with different thickness. In that case, the thinner film 3 switches at lower fields and is the low coercive layer or “soft” film, and the thicker film 2 switches at a higher field and is the high coercive layer or “hard” film. The application of a comparatively weak magnetic field can only alter the magnetic orientation of the “magnetically softer” layer 3, whereas a strong magnetic field can switch the magnetisation direction of both layers 2, 3. The resistance of a pseudo-spin valve cell 1 is lowest at the fields where the magnetisation direction of the hard film 2 is aligned with the magnetisation direction of the soft film 3.

In order to write a “1” or a “0” in a pseudo spin valve MRAM cell, a positive, respectively, a negative magnetic field is applied to that cell, which is sufficiently strong to change the magnetisation direction of the high coercive layer 2. The high coercive layer 2 is also known to be a “memory layer”. By applying a magnetic field which is strong enough to orient the magnetisation direction of the high coercive layer 2, also the magnetisation direction of the low coercive layer 3 is oriented. Writing is done by a conductor fabricated directly over, and inductively coupled to, the magnetic element. A current pulse travelling down the conductor generates a magnetic field parallel to the conductor's plane and close to its surface. The write current should be properly designed, so that it couples a field greater than the switching field into the element and switches the binary state. To write an opposite bit, the direction of the write current is reversed.

The low coercive layer 3 acts as a means of reading out the storage state, which is stored in the high coercive layer 2, and is therefore known to be a “reference layer”. When a low magnetic field is applied, the magnetisation direction of the low coercive layer 3 switches to be aligned with the low magnetic field, either parallel or anti-parallel with respect to the high coercive layer 2, without switching the magnetisation direction of the high coercive layer 2. Upon removing the applied field, the orientation of the reference layer must be stable, whether a parallel or an anti-parallel configuration is written. As these parallel and anti-parallel configurations have different resistances, the resistance can be read back at a later date to determine whether a “1” or a “0” has been stored.

In an MRAM array, comprising a plurality of MRAM cells, orthogonal lines pass under and over each bit, carrying current that produces the switching field. Each bit is designed so that it will not switch when current is applied to just one line, but will always switch when current is flowing through both lines that cross at the selected bit.

The physical and magnetic similarities between magnetic multilayers with copper interlayers and tunnelling magnetic multilayers with dielectric interlayers suggest that tunnelling memory cells can be constructed in much the same fashion as PSV cells, but with some limitations, as described in J. M. Daughton et al., “Applications of spin dependent transport materials”, J. Phys. D: Appl. Phys. 32 (1999) R169-177, such as the use of smaller sense currents, which cannot be used to aid in the switching of the cell. This suggests extra contacts and lower density for the TMR than for the PSV cell.

A typical TMR structure is described in S. Tehrani et al., “Progress and outlook for MRAM technology”, IEEE Transactions on Magnetics, Vol.35, No.5, September 1999, and is shown in FIG. 2. The TMR material stack 10 includes two magnetic layers, a fixed or pinned magnetic layer 11 and a free magnetic layer 12, both e.g. composed of NiFe, separated by a thin dielectric barrier 13, e.g. made of AlOx, and a mechanism, e.g. an IrMn pinning layer 14, to pin the polarisation of one of the fixed magnetic layer 11 in a fixed direction. For an uncoupled, free, ferromagnetic film, the magnetic orientation of the film displays a hysteretic behaviour pointing in the direction of the last applied saturating field. If a saturating field is applied and then taken away, the magnetic orientation of the free film will be in the direction of that field. If the direction of the applied saturating field is reversed and again taken away, the magnetic orientation of the film will be reversed. Thus in zero applied field, either orientation is possible.

A bottom electrode 15 and a top electrode 16 are provided underneath respectively on top of the multilayer stack. The polarisation direction of the free magnetic layer 12 is used for information storage, and only the magnetisation of the free layer 12 needs to be reversed for a write operation.

The resistance of the cell 10 is large, and the sense currents are small (μA range). The resistance of the memory bit is either low or high dependent on the relative polarisation, parallel or anti-parallel, of the free layer 12 with respect to the pinned or fixed magnetic layer 11. An externally applied field can switch the magnetisation of the free layer 12 between the two states (parallel or anti-parallel to the magnetisation direction of the fixed layer 11).

Uniformity of the MR ratio and the absolute resistance of the cell are critical in this architecture, since the absolute value of the TMR resistance is compared with a reference cell during read mode. If the active device resistances in a block of a memory show a large resistance variation, a signal error can occur when they are compared with a reference cell. The resistance of the TMR cell 10 is exponentially dependent on the thickness of the AlOx barrier 13. Therefore it is anticipated that small variations in the AlOx thickness would result in large variations in the resistance.

TMR structures are also described in U.S. Pat. No. 5,936,293 and U.S. Pat. No. 6,052,263.

In TMR multilayer devices 10, a sense current Iₛ has to be applied perpendicular to the layer planes (CPP—current perpendicular to plane) because the electrons have to tunnel through the barrier layer 13. In GMR devices, such as PSV 1, the sense current Iₛ usually flows in the plane of the layers (CIP—current in plane), although a CPP configuration provides a larger magneto-resistance effect. An example of a CPP GMR configuration is a dual spin valve, which has one high coercive layer in the middle, surrounded by two low coercive layers. The resistance is measured from top to bottom. In such a case, the MR effect is doubled.

It is to be estimated in view of memory density that within a few years time, a memory element cannot be larger than 200×200 nm. Such small cell dimensions will bring serious micro-magnetic problems, which may effect the stability of an MRAM. It has been shown that similarly small ferromagnetic particles are ferromagnetic at room temperature, but little is known about the stability of their domain structures over a long period of time. In the case of small structures, made of single magnetic layers, the demagnetising field actually helps to stabilise a single domain state. In the case of a spin valve, however, the presence of two ferromagnetic or ferrimagnetic layers means that the lowest energy state is when the two magnetisation directions are aligned anti-parallel. This effectively means that the parallel state of the cell is only metastable and that there is a large probability that the magnetisation directions of the two magnetic layers will relax to the lower energy anti-parallel configuration.

It is a disadvantage of known MRAM cells that they have to be read out in a particular way.

In case of spin valves with a fixed magnetisation direction, the data are stored in the free magnetic layer, which of course should not be disturbed by the read-out. In this case, the absolute resistance of a cell is measured to know its content; if desired, differentially with respect to a reference cell. The cell is selected by means of a switching element, usually a transistor, which implies that in this case one transistor is required per cell.

In case of PSV cells, a number of cells (N) are connected in series in a word line. The read-out is done by measuring the resistance of a word line (with the series of N cells), while subsequently a small positive and negative pulse are applied to the desired bit line. The accompanying magnetic field pulses are between the switching fields of the two ferromagnetic layers; thus the layer with the higher switching field (the data-storing layer) will remain unchanged, while the magnetisation of the other layer will be set in a defined direction and then be reversed. From the sign of the resulting resistance change in the word line it can be seen whether a “0” or a “1” is stored in the cell at the crossing point of the word and the bit line.

It is an object of the present invention to provide an MRAM cell with improved possibility to read out individual cells on a column of cells.

The above objective is accomplished by a magnetic device according to the present invention. Such a device comprises a first and a second ferromagnetic or ferrimagnetic layer separated by a non-magnetic spacer layer, thereby forming a multilayer configuration. The first ferromagnetic or ferrimagnetic layer has a coercivity of a first value and is used as a memory layer, and the second ferromagnetic or ferrimagnetic layer has a coercivity of a second value which is lower than the first value. Furthermore, the device comprises means for forcing the magnetisation directions of the first and second ferromagnetic or ferrimagnetic layers into an anti-parallel state when in a rest state.

According to one embodiment, the forcing means may make use of magnetic anisotropy. In that case, the composition of the second ferromagnetic or ferrimagnetic layer may be chosen so as to guarantee a coercivity value which is lower than a stray field emanating from the first ferromagnetic or ferrimagnetic layer.

According to another embodiment, the forcing means may make use of shape anisotropy. In that case, the first and the second ferromagnetic or ferrimagnetic layers may have a different shape.

The forcing means may make use of interlayer coupling between the first and the second ferromagnetic or ferrimagnetic layer via the spacer layer. The spacer layer may have a thickness which is chosen so that the interlayer coupling between the first and the second ferromagnetic or ferrimagnetic layer forces these into an anti-parallel state during a rest state.

The magnetic device according to the present invention may comprise a spin tunnel junction. Alternatively, the magnetic device may be based on Giant Magneto-Resistive (GMR) effect.

The present invention also provides an array of magnetic devices as described in any of the above embodiments.

According to one embodiment, such an array may comprise four magnetic devices according to the present invention arranged as a Wheatstone bridge.

According to another embodiment, the array is formed by magnetic devices coupled in series in columns and coupled in series in rows. The array further comprises a readout circuit imposing a potential on one row and one column and reading out a readout value representative of a value stored on the magnetic device at the meeting point of the one row and the one column. The readout circuit may impose a single electrical pulse to the one row and the one column to read out the readout value. In such an array, the values stored on the magnetic devices may represent either a “1” or a “0” of a binary code.

The present invention also provides the use as a magnetic memory element, as a magnetic sensor or as a magnetic read head of any of the embodiments of a magnetic device according to the present invention.

Furthermore, the present invention provides a method to read out a magnetic device according to any of the embodiments of the present invention, based on changing resistivity of the device with changing applied magnetic field. In another embodiment, the present invention provides a method to read out a magnetic device according to any of the embodiments of the present invention, based on changing magneto-refractive effect with changing applied magnetic field.

The essence of the present invention is that a magnetoresistive multilayer device is designed (for example, either a spin valve or a spin tunnel junction) which, always has the preference to align the magnetisation directions of the two ferromagnetic or ferrimagnetic layers in an anti-parallel direction. Three possible ways of doing this are discussed: magnetic anisotropy, shape anisotropy, and interlayer coupling. The devices in accordance with the present invention are particularly suitable for highly miniaturised devices.

Although there has been constant improvement, change and evolution of devices in this field, the present concepts are believed to represent substantial new and novel improvements, including departures from prior read-out practices, resulting in the provision of more efficient, stable and reliable devices of this nature. More particularly, there where everybody is trying to avoid coupling between layers, the present invention uses coupling between the two ferromagnetic or ferrimagnetic layers. A ferromagnetic layer can exist of a plurality of layers.

The objects and features of the present invention will become better understood through a consideration of the following description taken in conjunction with the drawings, which illustrate, by way of example, the principles of the invention. This description is given for the sake of example only, without limiting the scope of the invention. The reference figs. quoted below refer to the attached drawings.

FIG. 1 is a schematic illustration of a pseudo spin valve stack according to the prior art.

FIG. 2 is a schematic illustration of a typical TMR material stack as known in the prior art.

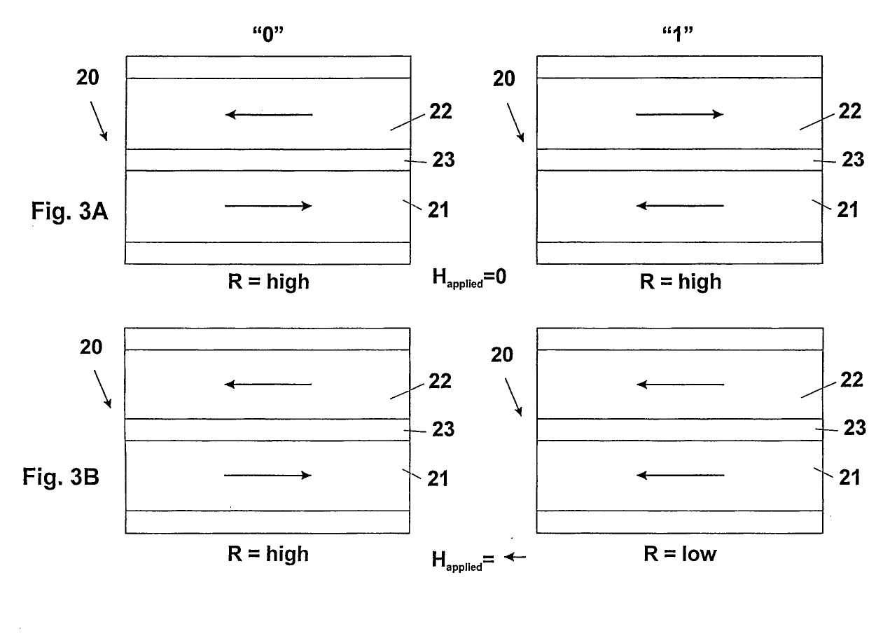

FIGS. 3A and 3B are a schematic illustration of “0” and “1” states of MRAM cells in respectively storage and readout states according to the present invention.

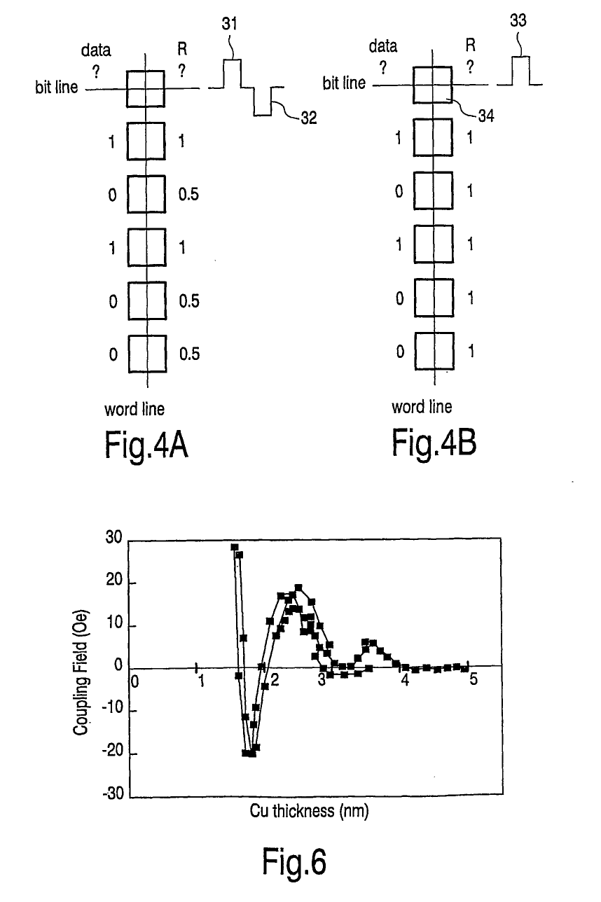

FIGS. 4A and 4B represent a line of MRAM cells read out in case of respectively a conventional method of data storage, and according to a method of the present invention.

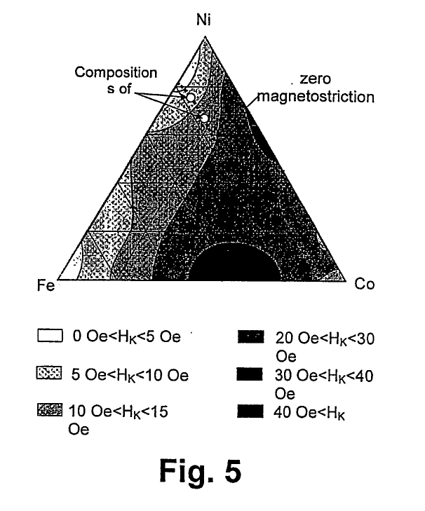

FIG. 5 is a graph showing the dependency of the anisotropy field on the composition of NiFeCo films.

FIG. 6 is a graph showing the dependence of the interlayer coupling on copper spacer thickness.

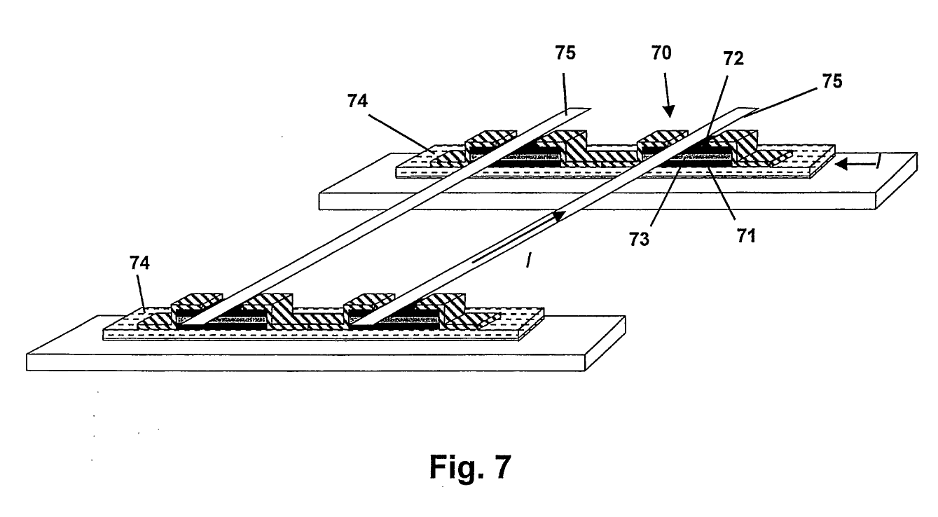

FIG. 7 shows part of a GMR based MRAM.

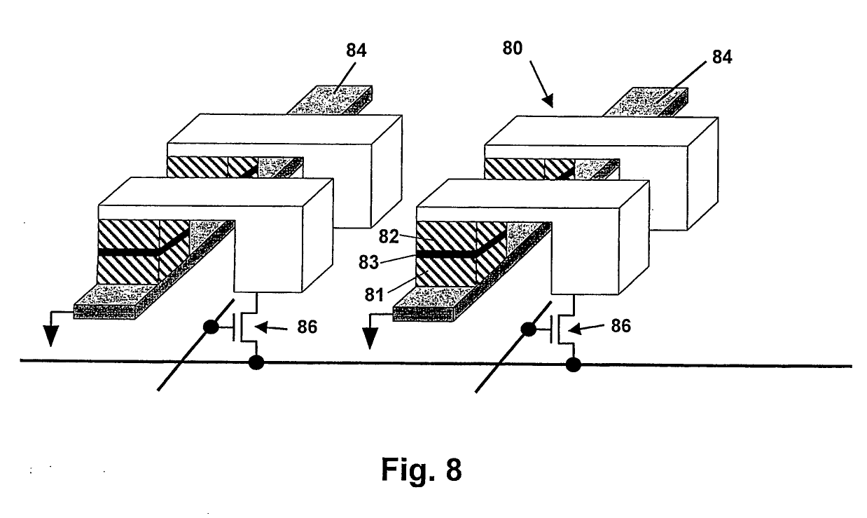

FIG. 8 shows part of a TMR based MRAM.

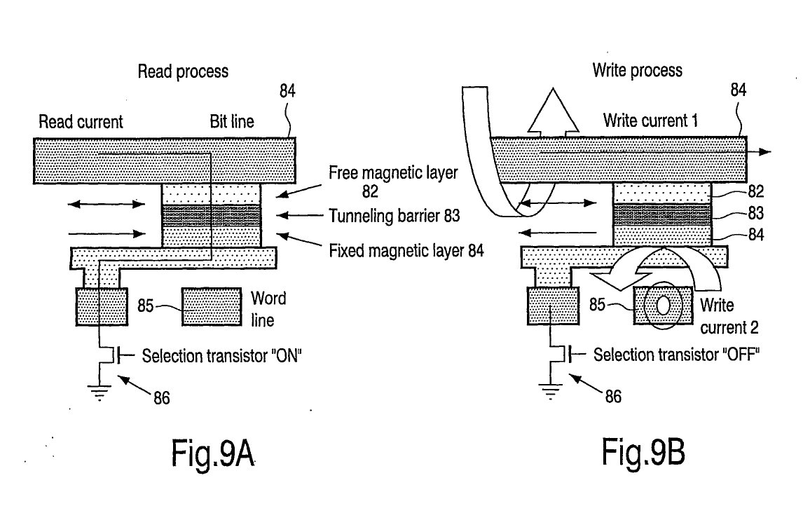

FIGS. 9A and 9B respectively show the current flow through a bit line and a word line associated with a TMR element for reading and writing such an element.

The present invention will be described with respect to particular embodiments and with reference to certain drawings but the invention is not limited thereto but only by the claims. The drawings described are only schematic and are non-limiting. In the drawings, the size of the devices and their layers has been exaggerated in some instances for illustrative purposes.

A magnetic device according to the present invention can resemble a PSV as known from the prior art structurally, and is shown for example in FIGS. 3A and 3B. It is a structure comprising at least two ferromagnetic or ferrimagnetic layers 21, 22 separated by a non-magnetic spacer layer 23, thereby forming a multilayer structure 20. One of the ferromagnetic layers, e.g. layer 21, is a high coercivity layer, and the other ferromagnetic layer, layer 22, is a low coercivity layer. The low coercivity layer 22 may for example have a coercivity value of less than 20 Oe, and the high coercivity layer 21 may have a coercivity value between 20 Oe and 200 Oe. The high coercivity layer 21 is used as a memory layer, i.e. the magnetisation direction of this layer 21 determines whether a “0” or a “1” value is stored in the cell 20. The coercivity value of the memory layer 21 is higher than the coercivity value of the other ferromagnetic layer 22. According to the present invention, a magnetic device 20 furthermore comprises means for forcing the magnetisation directions of the ferromagnetic layers 21, 22 in anti-parallel states when in a rest or normal state. By rest or normal state is meant a state in a low or zero magnetic field. The low magnetic field may be the earth's magnetic field (50 A/m) or any other background magnetic field imposed by the environment. Such means for forcing the magnetisation directions in anti-parallel states are described in more detail later on.

As in the prior art MRAM storage method, a sufficiently high write magnetic field is used for storing data in a magnetic device 20 according to the present invention, so that the orientation of magnetisation in the high coercivity layer 21 is re-orientated. The high coercivity layer 21 is then the memory layer. With regard to the prior art, the low coercivity layer 22 can be a very low coercivity layer (with a coercivity value between 0 and 20 Oe), and the high coercivity layer 21 has a coercivity comparable to the presently existing low coercivity layer in MRAM (with a coercivity value between 20 and 200 Oe); the high coercivity layer 21 should be easily switchable.

The storage state for cells 20 representing the values “0” and ”1” is illustrated in FIG. 3A. In order to address a cell 20 for writing in an array of cells, half the value of a necessary write current is applied to one row, and equal current is applied to one column. The full current then addresses a single cell in the array. This half-select process requires each cell's hysteresis loop to be square enough that applying and removing half the switching field leaves a cell in its initial state. Memory states are written in a cell 20 by applying the combined word current and sense current such that the total magnetic field generated exceeds the switching field of the hard magnetic layer 21. For example, in order to write the “1” state, a word current corresponding to the positive magnetic field is applied; in order to write the “0” state, word current is applied in the opposite direction. When the positive magnetic field is applied, the magnetisation direction of the hard magnetic layer 21 switches e.g. to the right. Instantaneously, also the magnetisation direction of the soft magnetic layer 22 switches to the same direction. Means for forcing the magnetisation direction of the hard magnetic layer 21 and the soft magnetic layer 22 in anti-parallel directions when in a rest state are however provided, such that, when the “1” state is written in the hard magnetic layer 21, and the magnetic field (applied by means of the writing current) is removed, the magnetisation direction of the soft magnetic layer 22 switches towards the anti-parallel direction.

According to the present invention, the layer 22 with the low coercivity is sufficiently magnetic soft, so that its magnetisation always relaxes to be anti-parallel to the memory layer in a rest state, i.e. when the field is removed. The low coercivity layer 22 is now referred to as the magnetic keeper layer, as it allows the stray magnetic flux from the memory layer 21 to be returned. Due to the keeper layer 22, all cells in a zero external field (H_{applied}=0) or in a low external field (e.g. H_{applied}=50 A/m) will have a low energy anti-parallel orientation of magnetisation, independent of the content of the cells. Furthermore, they will also have all the same (high) resistance.

In order to read the content of such an MRAM cell 20, a read pulse is used to set the magnetic orientation of the keeper layer 22 and to determine the orientation of the magnetisation in the high coercivity memory layer 21. This is illustrated in FIG. 3B, where cells 20 representing the values “0” and “1” are shown in the readout state. Memory states are read out from a cell 20 by applying an external field H_{applied} as shown in FIG. 3B, which is large enough to switch the magnetisation direction of the soft magnetic layer 22, but small enough to leave the magnetisation direction of the hard magnetic layer 21 unaltered. The magnetisation direction of the soft magnetic layer 22 of the cell 20 read out either was already aligned with the applied external field H_{applied}, or switches to align with that field. This means that for cells 20 which store a state in which the magnetisation direction of the hard magnetic layer 21 was aligned with the applied external magnetic field H_{applied} (“0” state in case of the example of FIG. 3B), the magnetisation direction of the soft magnetic layer 22 switches from anti-parallel to parallel. For cells 20 which store a state in which the magnetisation direction of the hard magnetic layer 21 was anti-parallel with the applied external field H_{applied} (“1” state in the example of FIG. 3B), and thus the magnetisation direction of the soft magnetic layer 22 was parallel with the applied external field H_{applied}, no switch takes place. Therefore, the resistance of the “0” state remains high (both magnetisation directions remain anti-parallel), while the resistance of the “1” state goes to low (both magnetisation directions become parallel).

When such a storage mechanism is used for MRAM, together with smaller cell dimensions, the low energy storage state (both magnetisation directions anti-parallel) will be much more stable than when a parallel alignment must be maintained. It is indeed true that upon reading, some of the cells will need to be switched to the parallel state, but this state is only required for the readout time, e.g. the parallel state remains stable for the about 1 ns readout time. The presence of an external magnetic field during readout also stabilises the parallel state.

With the method of storing data in an MRAM cell 20 according to the present invention, every cell 20 has the same resistance in the rest state, irrespective of its content, i.e. irrespective of whether a “1” or a “0” is stored in the cell 20. This shows an advantage for MRAM arrays where only one transistor is used per line of cells for read out. In FIG. 4 a line of cells which are written with data is considered.

If a conventional method of data storage is used (FIG. 4A), then reading the resistance of a selected MRAM cell 30 cannot be simply done by reading or measuring the total resistance of the word line. This is because the resistance on the word line is also dependent on the data in all other cells in the line. This problem is conventionally solved by first sending a read pulse 31 to the cell 30 to be read out (via the bit line which runs orthogonal to the word line) in e.g. a positive direction. The resistance of the cell 30 then has to be measured, and thereafter a negative pulse 32 is sent. The resistance has to be measured again, and upon subtraction of both resistances, the resistance of the cell 30 to be read out is found. This readout method has the disadvantage that it is slow.

FIG. 4B shows a part of an array of magnetic devices in accordance with the present invention, e.g. ganged in series in columns and rows. According to the present invention, and as can be seen in FIG. 41B, only one readout pulse 33 is required to readout a particular cell 34. The readout pulse is supplied by a readout circuit (not shown) and the resistance of the addressed element is also readout by this circuit by known means. The measured resistance is an absolute measurement of the state of the cell 34 to be read out. Indeed, it is known what the reference value is. If a pulse 33 is applied and the resistance changes then the content of the cell 34 is known to be “1”; if it does not change the content is known to be “0” (or vice versa if the opposite convention is used). The resistance measurement is independent from other elements which are also on the word line as they all have the same resistance in the rest state. Hence, as the resistances of the non-addressed elements on the word line are all the same and are also known, the effect of these resistances can be allowed for and/or eliminated. This property of the devices in accordance with the present invention can be used for GMR and TMR.

According to a first embodiment of the present invention, the means to force the device into an anti-parallel state when in the rest state, is magnetic anisotropy. The composition of the “keeper layer” 22 can be chosen to guarantee an extremely low coercivity. This low coercivity should be lower than the stray field emanating form the high coercivity layer 21. If this is the case then the keeper layer will move into an anti-parallel arrangement. The strength of the emanating field is difficult to estimate for various reasons, i.e. it is not uniform and it depends on both the aspect ratio of the high coercivity layer and the moment of the material from which it is made. If, however, it is assumed that the lower the coercivity the better, then the composition of the keeper layer 22 can be selected by using FIG. 5, for instance. Assuming that the field in an MRAM is applied along the magnetically easy axis of the material then the anisotropy field, as given in FIG. 5, is equivalent to the coercivity. From this figure for example the Ni₈₀Fe₂₀ alloy (permalloy) would appear to be a good candidate. The other ferromagnetic layer (with high coercivity H_{K}) can also be selected via FIG. 5. This should take into account the maximum generated field strength from the word/bit line. The most stable anti-parallel sensor is obtained when the function magnetisation x thickness is the same for both ferromagnetic layers. If the function magnetisation x thickness is the same for both ferromagnetic layers then there is no stray magnetic field. All the magnetic field from one layer can be returned via the keeper layer. If, on the contrary, the function magnetisation x thickness is different for both ferromagnetic layers there will be stray field which makes the anti-parallel energy state higher. If the device is to be used in the earth's magnetic field then the materials making up the layers as well as their shapes, thickness and sizes should be chosen so that the earth's magnetic field cannot change the magnetisation of the keeper layer.

It is, however, important to bear in mind that the thickness of the low coercivity layer, e.g. a permalloy film, is also of importance, as the coercivity tends to increase with increasing thickness. It may be advantageous to use thin NiFe for the low coercivity layer, as the coercivity value is low for such thin films. This has for example been described in K. J. Kirk et al., J. Phys. D: Appl. Phys. 34 (2001), FIG. 2 thereof showing the coercivity value in function of the thickness of the permalloy.

If one makes a single ferromagnetic layer into a rectangular particle then at a given width (usually about the width of a domain wall), the magnetisation will lie in a single domain state directed along the long axis. If, however, there are two ferromagnetic layers then an anti-parallel arrangement of the magnetisation M in the two layers will become energetically more favourable at a given aspect ratio. What this aspect ratio is can be calculated by a person skilled in the art or determined by experiment. If the keeper layer 22 has a sufficiently low coercivity then a small particle will always “flip” to the anti-parallel state.

According to a second embodiment of the present invention, the means to force the device into an anti-parallel state when in a rest state, is shape anisotropy. The preference of the magnetisation in a small ferromagnetic particle which is elongate to lie along the long axis can also be exploited to guarantee an anti-parallel rest state. This embodiment makes use of the fact that an elongate magnetic material, e.g. a strip of material has a tendency to magnetise itself in one of the directions along its longitudinal axis. Even if both layers are made from the same alloy then a high coercivity layer can be created by using a high aspect ratio for one of the layers. If the second layer (the low coercivity layer) has a lower aspect ratio then an anti-parallel state can always be obtained, as the magnetisation of the low aspect ratio particle can rotate to form an anti-parallel alignment.

Typically, the different layers in a multilayer structure have the same shape, but according to the present invention, in order to obtain different coercivities, different shapes of high and low coercivity layers can be used, e.g. ellipses with the large and small axes (or thus the easy axes) in different directions or, for spin tunnel junctions or GMR-CPP, a continuous soft magnetic layer, while the hard magnetic layer is etched in small stripes.

According to a third embodiment of the present invention, the means to force the device into an anti-parallel state when in a rest state, is interlayer coupling (coupling across the intermediate layer 23), often referred to as RKKY interlayer coupling. A graph showing the coupling as a function of Cu layer thickness can be seen in FIG. 6. There are three peaks visible, of which only the first two are very pronounced. At large thicknesses of the interlayer, the samples are decoupled. In known devices this is the preferred condition. It can be seen from FIG. 6 that by choosing a Cu layer thickness which coincides with a minimum in the coupling strength (thickness of about 1.8 nm), the energy of the anti-parallel state can be lowered. Another minimum in the coupling strength, existing but not shown in FIG. 6, falls at a Cu layer thickness of 0.8 nm. Materials other than copper which can be used are Ruthenium (Ru), Rhodium (Rh), Gold (Au), Iridium (Ir) or Chromium (Cr) in Fe/Cr multilayers. Thus, this embodiment of the present invention includes a thin conductive (metallic) interlayer whose thickness is chosen such as to form an anti-parallel state of the high and low coercivity layers in a rest state. This interlayer coupling can be used in itself or in combination with any of the above embodiments to ensure an anti-parallel alignment.

Both GMR and TMR devices can be used with the principle of anti-parallel state according to the present invention.

The magnetic layers of the devices according to the present invention should preferably be sputter deposited in a high vacuum machine with deposition rates in the Angstrom-per-second range. Particularly successful are physical vapour deposition, especially planar magnetron sputtering, and ion-beam deposition. It is also possible to evaporate or to use electro-deposition, though the quality of such devices tends to be lower.

It is important to control the magnetic properties of the magnetic layers, and this introduces special requirements on the deposition process. For example, most ferromagnetic materials have an inherent magnetic anisotropy that is related to ordering on atomic scale. The direction of this anisotropy can be set during the deposition of the layer by applying a magnetic field across the wafer. The resulting uniaxial anisotropy is observed as magnetic easy and hard directions in the magnetisation of the layer. Since the anisotropy axis affects the switching behaviour of he material, the deposition system must be capable of projecting a uniform magnetic field across the wafer, typically in the 20-100 Oe range, during deposition. Also coercivity is dependent on the deposition process, and must be controlled by the choice of magnetic alloy and deposition conditions. The (soft and hard) magnetic films should, preferably, each be of uniform thickness.

All other layers used are similar to those used in the pseudo spin valve of conventional devices.

The present invention also includes insulating tunnel barriers in TMR devices. Various methods are known for producing insulating tunnel barrier TMR devices. The best results are obtained for AlOx tunnel-barrier layers made by depositing a metallic aluminium layer, and then oxidising it by one of several methods, such as e.g. plasma oxidation, oxidation in air, ion-beam oxidation, oxidation by glow-discharge plasma, atomic-oxygen exposure, or ultraviolet-stimulated O₂ exposure. The tunnel barrier is very thin, preferably less than 20 ÅA. In addition to being very smooth an free of pinholes, it must be extremely uniform over the wafer, since small variations in the AlOx thickness result in large variations in the resistance.

The devices according to the present invention can be any device sensitive to a magnetic field, such as e.g. memory cells (MRAM cells), sensors, and magnetic field read heads.

One type of sensor uses a Wheatstone bridge, in which four magneto-resistive elements according to the present invention are arranged so that at zero applied field the output current of the bridge is also zero. Another type of sensor is a rotary position sensor, in which when an external magnet is rotated 180° over a stripe of magnetic devices according to the present invention, the resistance changes from minimum to maximum, and during the next 180° of rotation the resistance returns to its minimum again.

FIG. 7 shows part of a GMR-based MRAM array comprising rows and columns of GMR elements 70. Each element 70 of the GMR-based MRAM is a three-layer structure, comprising a high coercivity layer 71 and a low coercivity layer 72, with in between a non-magnetic conductor interlayer 73. GMR elements 70 on one row are connected by a bit line and GMR elements 70 on one column are connected by a word line 75. These bit lines 74 and word lines 75 are used to write the magnetisation direction in the high coercivity layer 71 of a selected GMR element 70, and to read out the content of a selected GMR element 70. Writing is done by at the same time sending a relatively large current through the word line 75 and through the bit line 74, which word line 75 and bit line 74 cross at the selected GMR element 70. These combined currents are such that the total magnetic field generated at the selected GMR element 70 makes the magnetisation of the high coercivity layer 71 to be directed in a particular direction, depending on whether a “0” or a “1” is to be written in the GMR element. Reading a bit, or thus determining the magnetic orientation of the high coercivity layer 71 is done by a readout pulse on the bit line 74, which pulse is large enough to generate a magnetic field that can switch the magnetisation direction of the low coercivity layer 72. The resistance of the GMR element 70 is measured, and from this measurement, the content of the GMR element 70 is known.

FIG. 8 shows part of a TMR-based MRAM array comprising rows and columns of TMR elements 80. Each element 80 is a layered structure, comprising a fixed or pinned layer 81, a free layer 82 and a dielectric barrier 83 in between. By applying a small voltage over the sandwich of ferromagnetic or ferrimagnetic layers 81, 82 with the dielectric layer 83 therebetween, electrons can tunnel through the dielectric barrier 83. Writing is done by at the same time applying a first write current through a bit line 84 and a second write current through a word line 85, as shown in FIG. 9B, the word line 85 and the bit line 84 crossing at the selected TMR element 80. These combined currents are such that the total magnetic field generated at the selected TMR element 80 makes the magnetisation of the high coercivity layer 81 to be directed in a particular direction, depending on whether a “0” or a “1” is to be written in the TMR element. Reading a bit, or thus determining the magnetic orientation of the high coercivity layer 81 of a selected TMR element 80 is done by a readout pulse on the bit line 84, which can switch the magnetisation direction of the low coercivity layer 82. This is shown in FIG. 9A. The resistance of the TMR element 80 is measured, and from this measurement, the content of the TMR element 80 is known.

In the configuration of FIG. 8, one transistor 86 or switching element per TMR element 80 is required. When such a selection transistor 86 is ON for a selected TMR element 80, a current pulse on the bit line 84 can tunnel through the selected TMR element 80.

The present invention includes use of devices as read heads for magnetic disk drives. The capacity of disk drives continues to grow rapidly as they shrink in size. This means that more and more data is written into smaller amounts of space. The data are written as tiny regions of magnetisation on a disk covered with a thin film of magnetic material. The information (“1” or “0”) is stored as the direction of the magnetisation of these regions. The information is read by sensing the magnetic fields just above these magnetised regions on the disk. Read sensors according to the present invention can be made in such a way that a very small magnetic field causes a detectable change in its resistivity, and such changes in resistivity produce electrical signals corresponding to the data on the disk which are sent e.g. to a computer.

Instead of resistance, another property may be measured, such as optical properties, e.g. the magneto-refractive effect, which is proportional to resistance: it represents the effect that a change in conductivity due to an applied magnetic field leads to a change in the refractive index. Absorption and reflection coefficients of light are dependent on the refractive index and hence the intensity of transmitted and reflected infra-red light is related to the magneto-resistance. As light is measured, an ohmic contact is not necessary.

A device according to the present invention is intended to form a small cell, e.g. a memory cell, preferably having a largest dimension smaller than 50 μm, most preferred smaller than 1 μm.

While the invention has been shown and described with reference to preferred embodiments, it will be understood by those skilled in the art that various changes or modifications in form and detail may be made without departing from the scope and spirit of this invention. More particularly, the preferred embodiment described is related to MRAM cells, but it is not intended to limit the scope of the invention to MRAM cells. Further, wherever in the above description reference is made to a ferromagnetic layer, the use of a ferromagnetic film or layer is not excluded. Wherever reference is made to a ferromagnetic or ferrimagnetic layer, it should be understood that this layer may be made up of a plurality of layers.

1. Magnetic device comprising
a first and a second ferromagnetic or ferrimagnetic layer separated by a non-magnetic spacer layer thereby forming a multilayer configuration, the first ferromagnetic or ferrimagnetic layer having a coercivity of a first value and being used as a memory layer, and the second ferromagnetic or ferrimagnetic layer having a second coercivity of a value lower than the first value, and
means for forcing the magnetisation directions of the first and second ferromagnetic or ferrimagnetic layer into an anti-parallel state when in a rest state.

2. Magnetic device according to claim 1, wherein the forcing means makes use of magnetic anisotropy.

3. Magnetic device according to claim 2, wherein the composition of the second ferromagnetic or ferrimagnetic layer is chosen so as to guarantee a coercivity value which is lower than a stray field emanating from the first ferromagnetic or ferrimagnetic layer.

4. Magnetic device according to claim 1, wherein the forcing means makes use of shape anisotropy.

5. Magnetic device according to claim 4, wherein the first and the second ferromagnetic or ferrimagnetic layers have a different shape.

6. Magnetic device according to claim 1, wherein the forcing means makes use of interlayer coupling between the first and the second ferromagnetic or ferrimagnetic layer via the spacer layer.

7. Magnetic device according to claim 6, wherein the spacer layer has a thickness chosen so that the interlayer coupling between the first and the second ferromagnetic or ferrimagnetic layer forces these into an anti-parallel state during a rest state.

8. Magnetic device according to claim 1, wherein the device comprises a spin tunnel junction.

9. Magnetic device according to claim 1, wherein the device is based on Giant Magneto-Resistive (GMR) effect.

10. An array of magnetic devices according to claim 1.

11. The array according to claim 10, comprising four magnetic devices according to claim 1, arranged as a Wheatstone bridge.

12. The array according to claim 10, wherein the magnetic devices are coupled in series in columns and coupled in series in rows, further comprising a readout circuit, the readout circuit imposing a potential on one row and one column and reading out a readout value representative of a value stored on the magnetic device at the meeting point of the one row and the one column.

13. The array according to claim 12, wherein the values stored on the magnetic devices represent either a “1” or a “0” of a binary code.

14. The array according to claim 12, wherein the readout circuit imposes a single electrical pulse to the one row and the one column to read out the readout value.

15. Use of a device according to according to claim 1, as a magnetic memory element.

16. Use of a device according to according to claim 1, as a magnetic sensor.

17. Use of a device according to claim 1, as a magnetic read head.

18. Method to read out a magnetic device according to claim 1, based on changing resistivity of the device with changing applied magnetic field.

19. Method to read out a magnetic device according to claim 1, based on changing magneto-refractive effect with changing applied magnetic field.
